(19) United States
(12) Patent Application Publication
(10) Pub. No.: US 2026/0237924 A1
(43) Pub. Date: Aug. 13, 2026

(54) CIRCUIT BOARD RIGID CONNECTORS

(71) Applicant: Nvidia Corporation, Santa Clara, CA (US)

(72) Inventors: Kevin Darrel Conn, Montgomery, TX (US); Cong Gao, Pflugerville, TX (US); Karl Joseph Bois, Fort Collins, CO (US)

(21) Appl. No.: 19/179,979

(22) Filed: Apr. 15, 2025

Related U.S. Application Data
(60) Provisional application No. 63/756,613, filed on Feb. 10, 2025.

(51) Int. Cl. H01R 12/71; H01R 12/70; H01R 12/79; H05K 7/14

(52) U.S. Cl. CPC H01R 12/716; H01R 12/7041; H01R 12/7047; H01R 12/7082; H01R 12/79; H05K 7/1452

(57) ABSTRACT

Systems and methods disclosed herein may be used to provide rigid connectors using a circuit board assembly having a printed circuit board (PCB) with surface contact pads. The surface contact pads may be individually encompassed by rigid connector forms having individual external flanges. A rigid frame may overlay the external flanges to maintain a position for the rigid connector forms with respect to the PCB.

### CROSS-REFERENCE TO RELATED APPLICATION(S)

This is a non-provisional application that is related to and that claims the benefit of priority from U.S. provisional patent application Ser. No. 63/756,613, filed Feb. 10, 2025, and entitled “CIRCUIT BOARD RIGID CONNECTORS,” the entire contents of which is incorporated by reference herein and form a part of this specification for all intents and purposes.

### TECHNICAL FIELD

This disclosure relates to circuit board connectors and, in at least one embodiment, pertains to high-speed signaling and other connectors that are rigid connectors for a printed circuit board.

### BACKGROUND

A rack, server, or other computing component may include circuit boards that may be printed circuit boards (PCBs), including backplanes and midplanes, associated with signaling circuits.

### BRIEF DESCRIPTION OF DRAWINGS

FIG. 1A illustrates aspects of a rigid connector form having an individual external flange in support of rigid connectors for a printed circuit board (PCB), according to at least one embodiment;

FIG. 1B illustrates aspects of a PCB with multiple rigid connector forms adhered thereto, according to at least one embodiment;

FIG. 1C illustrates aspects of a rigid frame to overlay the external flanges of rigid connector forms to maintain a position for the rigid connector forms with respect to the PCB, according to at least one embodiment;

FIG. 1D illustrates aspects of a rigid plate associated with the rigid frame from an opposite side of the PCB relative to the rigid frame, according to at least one embodiment;

FIG. 1E illustrates aspects of a rigid plate or a rigid frame, according to at least one embodiment;

FIG. 2A illustrates aspects of a dual-sided midplane with rigid connector forms, according to at least one embodiment;

FIG. 2B illustrates further details of a dual-sided midplane with rigid connector forms, according to at least one embodiment;

FIG. 2C illustrates further details of a rigid connector form over surface contact pads of a PCB in a transparent section-view, according to at least one embodiment;

FIGS. 3A and 3B illustrate spring-loaded features of the rigid connector forms, according to at least one embodiment;

FIG. 3C illustrates a section view of a rigid frame over an external flange of a rigid connector form, in support of rigid connectors for a PCB, according to at least one embodiment;

FIG. 4A illustrates an example datacenter to apply at least one embodiment in FIGS. 1-3C and 5-7;

FIG. 4B illustrates aspects of an example rack to apply at least one embodiment in FIGS. 1-3C and 5-7;

FIG. 5 illustrates a process flow or method associated with rigid connectors for a PCB, according to at least one embodiment;

FIG. 6A illustrates an example datacenter, in which at least one embodiment may be used;

FIG. 6B is a block diagram that schematically illustrates a computing system that may be a datacenter or a High-Performance Computing (HPC) cluster, in which at least one embodiment from FIGS. 1A-5 may be used;

FIG. 6C illustrates a computer system, according to at least one example, in which at least one embodiment from FIGS. 1A-5 may be used; and

FIG. 7 illustrates an example network configuration of components that can be used to implement aspects of various embodiments.

### DETAILED DESCRIPTION

In the following description, various embodiments will be described. For purposes of explanation, specific configurations, and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Connectors used with the PCBs may require mounting screws and mounting through-holes or posts to fasten the connectors to the PCBs. A PCB may also include small connector ground pins that may act as retention pins for the connector. At least the screws may be required for mechanical retention and may ensure adequate contact from the connector's conductors to contacts of the PCB. The screws may create issues with respect to the through-holes being drilled through a total thickness of the PCB. The screws may limit a density of interconnects that may be mounted on a same side of the PCB or for connectors located on opposite of the PCB. This may also create obstruction for the screw locations. In one example, the through-holes or drilled holes used for the mounting screws may void important portions of useful areas in the PCB. Such useful areas may be otherwise used for signal lines routed through each layer of a PCB.

The circuit board assembly herein, such as a backplane or a midplane that may include a printed circuit board (PCB), may receive connections from external components of a rack or a server. The PCB may have multiple surface contact pads. The surface contact pads may be individually encompassed by plastic rigid connector forms having individual external flanges, which may be formed by plastic molding. The flanges may be voids shaped to mold the connector outer body having a flange geometry is pressed on one or all connectors on a face or side of the PCB. A rigid frame that may be of a metal material, including aluminum, titanium, stainless steel, or other rigid metal, may be overlaid on the external flanges to maintain a position for the rigid connector forms with respect to the PCB to optimize strength and weight.

As described above, the external flange of the rigid connector form creates a pressing surface on an underside of a rigid connector form. The pressing surface may ensure that there is a secure connection with the ground and signal pins on the underside of the connector. The rigid frame is associated with the external flange and pressed onto one or more connectors on the PCB face. Equal pressure should be applied around the entire perimeter of the connector. Achieving this can be challenging due to machining tolerances and the variability in the connector housing. Spring-loaded features may be associated with the external flanges of the rigid connector forms. The spring-loaded features may allow tolerance for one or more of a pressure applied through the rigid frame to the rigid connector forms, a force applied through the rigid frame to the rigid connector forms, a distance between the rigid frame and the PCB based in part on a warping of the PCB, or an electrical contact to be made between the surface contact pads and connectors of the rigid connector forms or connectors to be associated with the rigid connector forms. The spring-loaded features may compensate for any tolerance discrepancies among the components. The spring-loaded features may be integrated into the flange of the connector housing, providing consistent tolerance accommodation, or into the rigid plate.

Further, the problem addressed is that connectors for PCBs may require mounting screws to fasten the connector to a PCB. The screws may require mechanical retention and may require ensuring adequate electrical contact between the connector to the PCB. The requirement for mounting screws may create issues of holes needing to be drilled through a total thickness of the PCB and screws or other fasteners to be used, which may limit a density of interconnects that may be available on a side of the PCB or of the connectors located on an opposite side of the PCB. This issue may create obstruction of the screw locations, in one example. Another issue may be that the drill holes required by the mounting screws may void useful areas on the PCB where signal lines may be routed on each layer of the PCB. The circuit board assembly here may use rigid connector forms with external flanges that are held down by a rigid frame having fasteners only at its perimeter. The rigid plate may be milled to fit the perimeter of the PCB connectors (such as surface contact pads) and provide clearance for the external flange to pressure down against the PCB. The additional use of spring-loaded features with the external flanges may ensure allowances for various electrical and mechanical requirements between the rigid connector forms and the PCB.

The connectors herein may support different media of transmission. A medium of transmission as used herein may allow networking capabilities associated with direct attach copper (DAC), active copper cable (ACC), active optical cables (AOCs), cable assembly with OSFP connectors or the like) or interconnect utilized by switch modules (including PCB connectors forming a board-to-board connection or a cabled header forming a board-to-cabled connection). The network connectors may each be configured to connect to a networking device of any type (e.g., QSFP, Direct Attach Copper, active optical cables (AOC), etc.), and may thus be dimensioned (e.g., sized and shaped) to mate with or otherwise connect to any corresponding networking device. The cable connector may be of any type (e.g., an AOC connector, Ethernet connector, Direct Attach Copper connector, Active Optical Module, or the like). A PCB is used to electrically connect electronic components using conductive pathways, or traces, etched from metal sheets. In many electronic systems, one or more very large-scale integrated circuit (“VLSI”) components are coupled to a host system printed circuit board (“PCB”). Such VLSI components may include, for example, central processing unit “CPU) devices and graphics processing unit (“GPU”) devices. The PCB may hold at least one processing circuitry. The processing circuitry may comprise hardware, such as an application specific integrated circuit (ASIC). The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted. Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. It should be appreciated that any appropriate type of electrical or optical component or collection of electrical or optical components may be suitable for inclusion in the processing circuitry. Numerous example embodiments will be described below in which a semiconductor package is mounted within a through hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor package is mounted may comprise an add-in card, such as a PCIe card, that is configured to be coupled to a system board or motherboard of a host system. In other embodiments, the PCB to which the semiconductor package is mounted may be the system board or motherboard of the host system itself. Moreover, the system board or the motherboard may be associated with any type of host system. For example, the PCB may comprise the system board in a multi-node rack-mounted server, or it may comprise the motherboard of a workstation, desktop, laptop, or mobile device. Other embodiments are also possible.

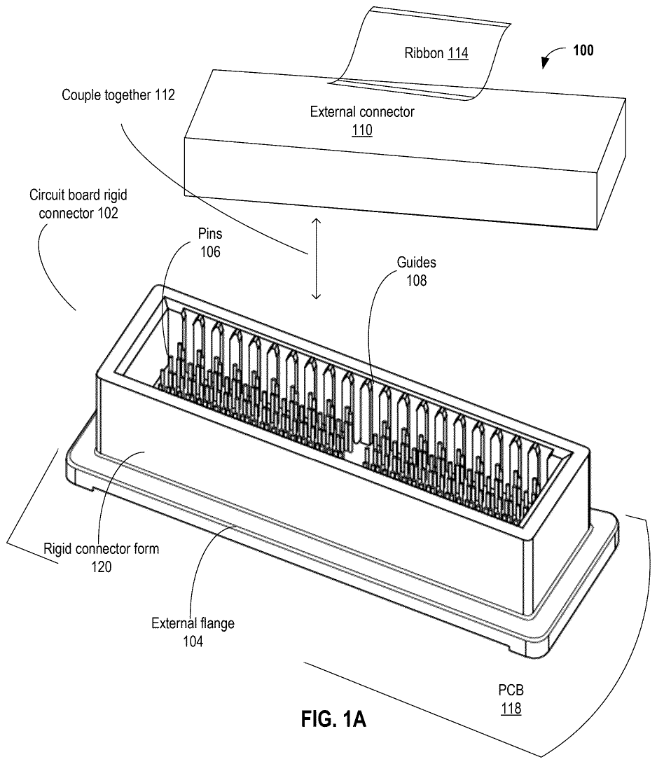

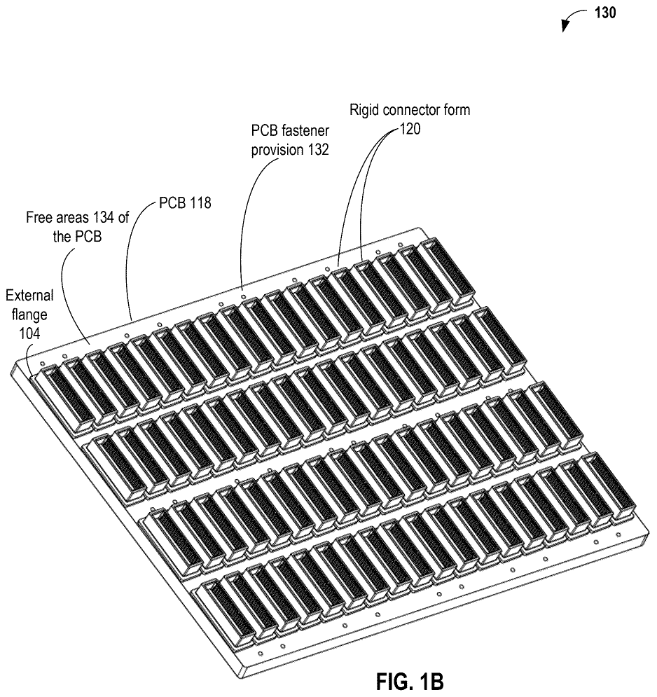

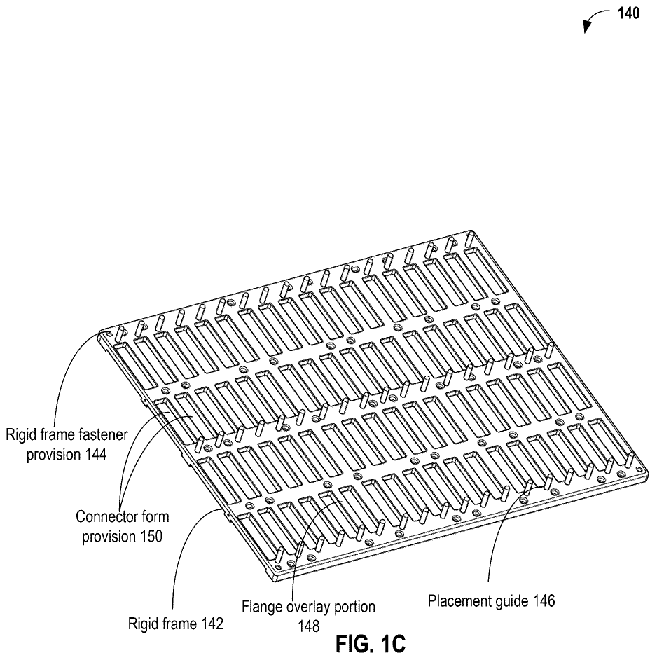

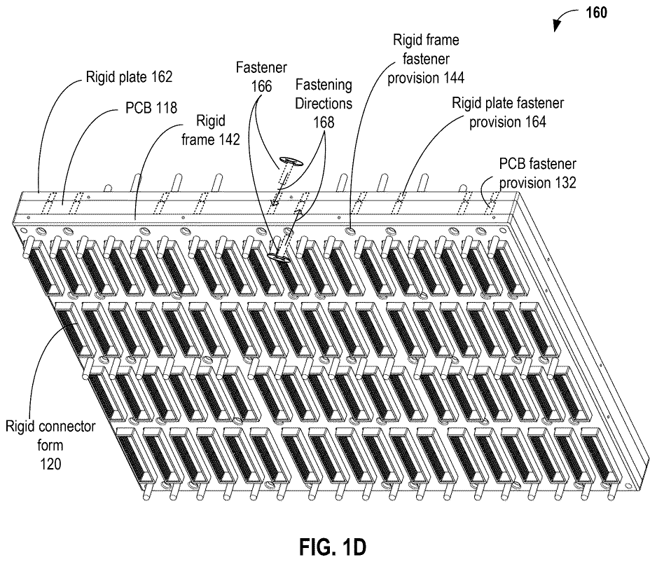

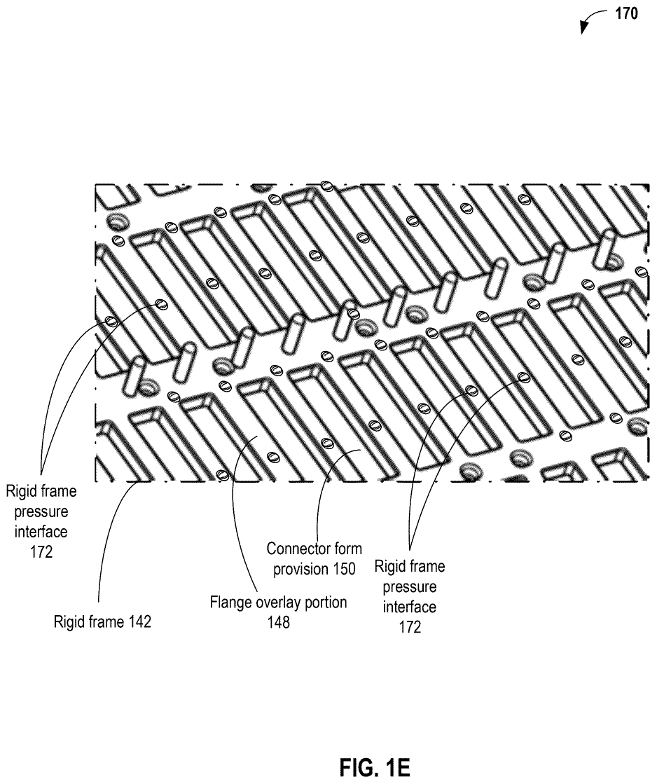

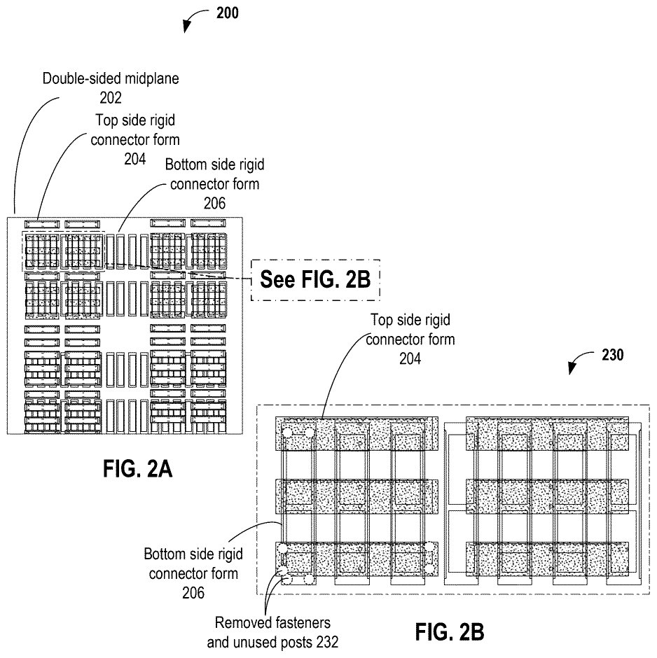

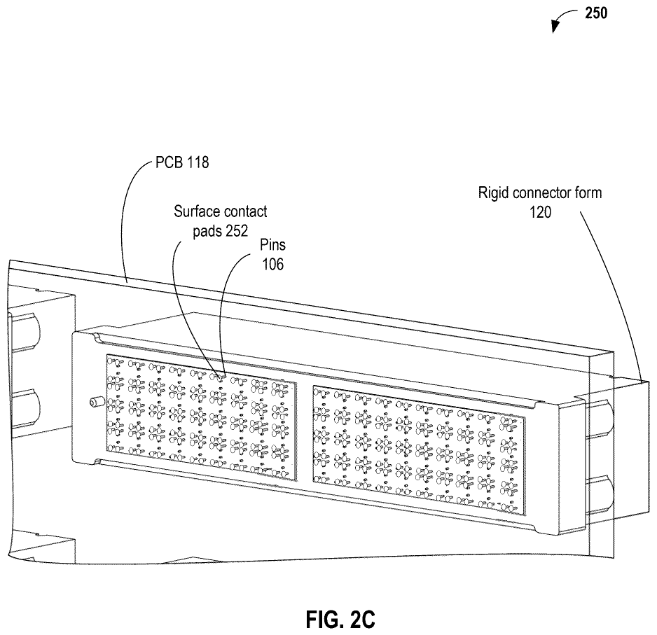

FIG. 1A illustrates connections in the aspects 100, using a rigid connector form having an individual external flange in support of rigid connectors for a circuit board assembly having a printed circuit board (PCB), according to at least one embodiment. In one example, the connections 100 are made up of at least one circuit board rigid connector 102 that may be part of a circuit board assembly. The circuit board rigid connector 102 may be associated with a PCB 118 (illustrated only in part) having surface contact pads 252 (such as in FIG. 2C). The surface contact pads 252 may be individually encompassed by a rigid connector form 120 of the circuit board rigid connector 102. Each rigid connector form 120 may have an external flange 104. While one is illustrated, there may be multiple such circuit board rigid connector 102 disposed on a PCB 118 (as discussed with respect to at least FIGS. 1B to 3C herein). A rigid frame (as discussed and described with respect to at least FIG. 1C) may overlay the external flange 104 to maintain a position for the rigid connector form 120 with respect to the PCB 118. When multiple circuit board rigid connectors 102 are disposed on a PCB 118, the rigid frame may be configured or adapted to overlay individual external flanges of multiple rigid connector forms to maintain a position for the rigid connector forms with respect to the PCB 118.

FIG. 1A also illustrates that there may be connectors of the rigid connector form 120. For example, there may be pins 106 extending from the surface contact pads 252. The pins 106 may extend through the rigid connector form 120 to allow connection with an external connector 110 by a plug-in to the rigid connector form 120. The pins 106 may be part of the rigid connector form 120 to extend the surface contact pads 252, in one example. In another example, the external connector 110 may include the pins 106 to reach the surface contact pads 252. The pins 106 may be compliant pins which may deform when pressed into the surface contact pads 252, forming a contact that holds the rigid connector form 120 in place. Alternatively, adhesives can be used to hold connectors in place, as initial retention, before the rigid frame is applied. This ensures that the rigid connector form having the pins 106 remain securely positioned during assembly.

For example, positions may be determined for the rigid connector forms on the PCB based at least in part on locations of surface contact pads on the PCB. Then, the rigid connector forms may be provided with an adhesive, or the PCB may be provided with an adhesive. The adhesive may be provided to be coincidental on the external flange of the rigid connector forms. The adhesive may be between an underside of the individual external flanges and the PCB. Once all the rigid connector forms are adhered to the PCB, the rigid frame may be applied with or without the rigid plate. Fasteners may hold the circuit board assembly of the PCB, the rigid frame, and the rigid plate together at unused areas of the PCB.

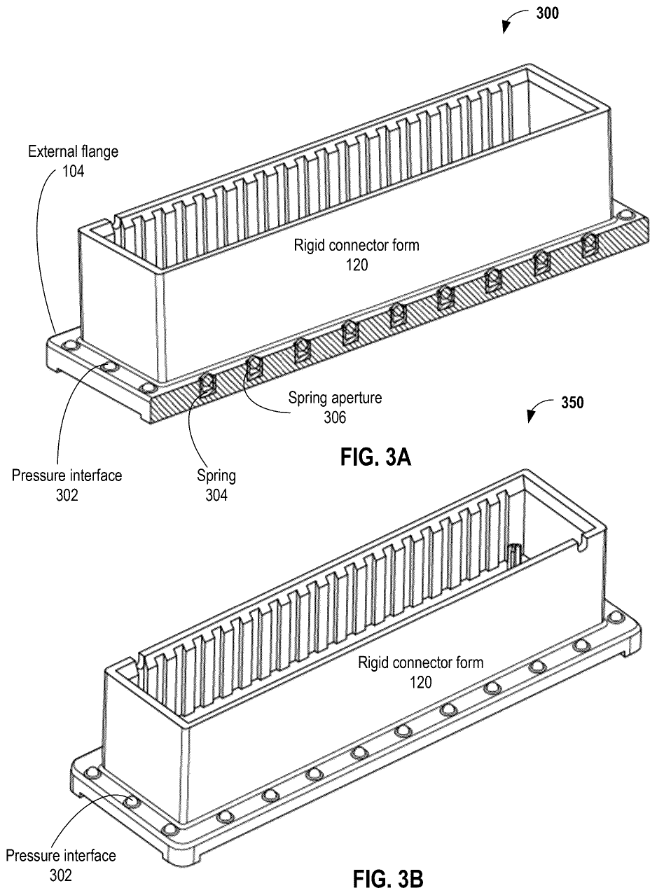

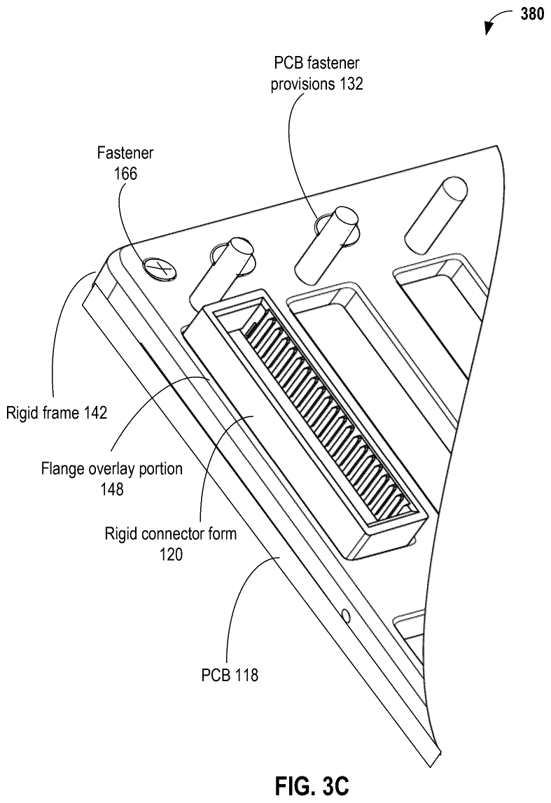

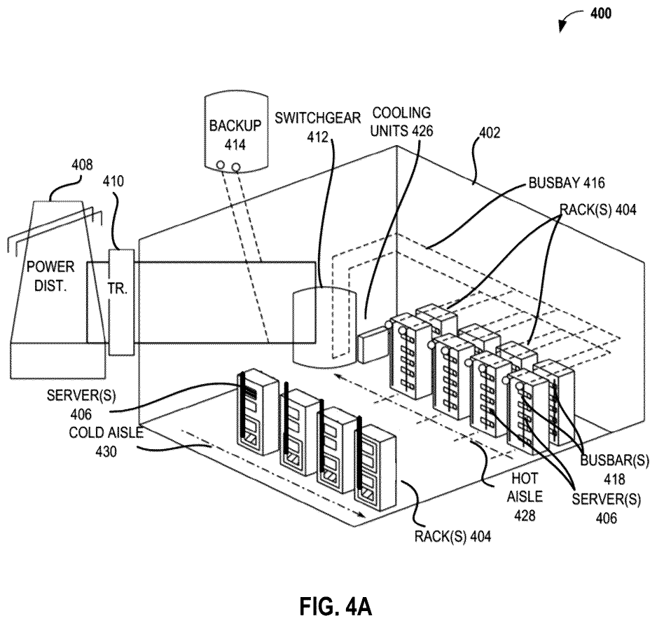

In another example, the pins 106, being compliant pins, may also provide initial retention, but they may not be sufficient for the product's life or guaranteed reliability. The plate is necessary to ensure long-term retention and electrical reliability. The external connector 110 may be supported by a ribbon 114 or other feature to allow communication from the external connector 110 to a circuit of the PCB 118. In one example, the external connector 110 may be a female interface to the rigid connector form 120 and may be mated to allow a daughter card to be used with the PCB 118. In this manner, it is possible to couple together 112, by a plug-in for instance, a circuit board rigid connector 102 to the surface contact pads 252 and to external connectors 110. The plug-in may be assisted by guides 108 in the circuit board rigid connector 102. In another example, as illustrated and described with respect to FIGS. 1D, 3A, and 3B, there need not be pins 106 extending from the surface contact pads. The external connector 110 may have pins to suitably couple together 112 with the surface contact pads. A rigid connector form 120 may be prepared from a plastic or other non-electronically conductive material.

FIG. 1B illustrates aspects 130 of a PCB with multiple rigid connector forms adhered thereto, according to at least one embodiment. The aspects 130 include a PCB 118 having multiple rigid connector forms 120, where individual ones of the rigid connector forms 120 may encompass surface contact pads of different connectors for different circuits, including for signaling circuits. The rigid connector forms 120 may be able to couple to different form-factors of connectors on at least the inside based in part on different types of guides 108 to suit the different form-factors used. The outside of the rigid connector forms 120 may be standardized to similar dimensions and similar external flanges 104 to receive a singular rigid frame thereon. The aspects described in the plural in one or more of FIGS. herein may be plural versions of the aspects described in the singular in the FIGS., unless otherwise indicated.

FIG. 1B also illustrates that there may be PCB fastener provisions 132 for fasteners at a perimeter of the PCB 118. The perimeter may include free areas 134 of the PCB in which there may not be signal components or other circuitry. The rigid connector forms 120 themselves are devoid of fasteners to the PCB 118. The rigid frame may be fastened through the PCB fastener provisions 132 of the PCB 118 to ensure that adequate pressure is applied to all the rigid connector forms 120 through their respective external flanges 104, without fasteners on the rigid connector forms 120 themselves. In this manner, it is possible to eliminate screws that may otherwise be required for mechanical retention, to eliminate the need to solder the connector or to have retention pins as part of the connector design, and to ensure adequate contact from the connector's conductors (such as pins) to contacts (such as the surface contact pads) of the PCB 118. In this manner, it is possible to avoid issues with respect to through-holes that may otherwise be required by being drilled through a total thickness of the PCB 118. In this manner, it is also possible to avoid any limit to a density of interconnects that may be mounted on a same side of the PCB 118 to improve routing channels interference in dense designs, or for connectors located on opposite of the PCB 118, which may otherwise create obstruction for the screw locations. This allows for a more efficient assembly process without individual screws. The circuit board assembly may include a process involving a rigid frame to hold rigid connector form in place without individual screws, ensuring uniform compression and electrical reliability, as it applies consistent pressure uniformly across all the rigid connector forms regardless of any waviness or flatness issues with the plate, eliminating the need for individual screws. In one example, it is possible to preserve and use important portions of useful areas in the PCB 118. Such useful areas may now be used for signal lines routed through each layer of a PCB 118

FIG. 1C illustrates aspects 140 of a rigid frame to overlay the external flanges of rigid connector forms to maintain a position for the rigid connector forms with respect to the PCB, according to at least one embodiment. The aspects 140 include use of a rigid frame 142 to overlay the external flanges 104 of the rigid connector forms 120. This allows maintenance of a position for the rigid connector forms 120 with respect to the PCB 118. The rigid frame 142 may include connector form provisions 150 for receiving therethrough the rigid connector forms 120 while flange overlay portion 148 of the rigid frame 142 may be used to overlay the external flanges 104. The rigid frame 142 may also include rigid frame fastener provisions 144 at least at a perimeter of the rigid frame 142. The rigid frame fastener provisions 144 may be used to receive fasteners, through the PCB fastener provisions 132, to fasten the rigid frame to the PCB 118, while the rigid connector forms 120 themselves are devoid of fasteners to the PCB. FIG. 1C also illustrates that the rigid frame includes rigid frame fastener provisions 144 that are to be used for fasteners at locations that coincide with free areas 134 of the PCB that are free from circuit or signal components. The aspects 140 may also include one or more placement guides 146 to allow positioning of the rigid frame 142 prior to fastening to the PCB 118.

FIG. 1D illustrates aspects 160 of a rigid plate associated with the rigid frame from an opposite side of the PCB relative to the rigid frame, according to at least one embodiment. The aspects 160 include a rigid plate 162, which may be associated with the rigid frame 142 from an opposite side of the PCB 118, relative to the rigid frame 142. The rigid plate 162 may include rigid plate fastener provisions 144 to receive fasteners 166 through rigid frame fasteners provisions 144 of the rigid frame. While two fasteners 166 are illustrated, it is appreciated that uniform distribution of fasteners through the fastener provisions 144, 164, 132 are used to at least maintain a position for the rigid connector forms 120 with respect to the PCB 118.

The fasteners 166 may be received from either side of the PCB 118, as illustrated by the different fastening directions 168. In one example, the rigid connector forms 120 may be adhered to the PCB 118 so that they are temporarily in position with respect to the PCB 118. One or more of the rigid frame 142 or the rigid plate 162 may be fastened using the fasteners 166 for a removable association and for providing at least predetermined pressures to maintain a position for the plurality of rigid connector forms 120 with respect to the PCB. External connections, as illustrated in FIG. 1A may be made up of the rigid connector forms 120.

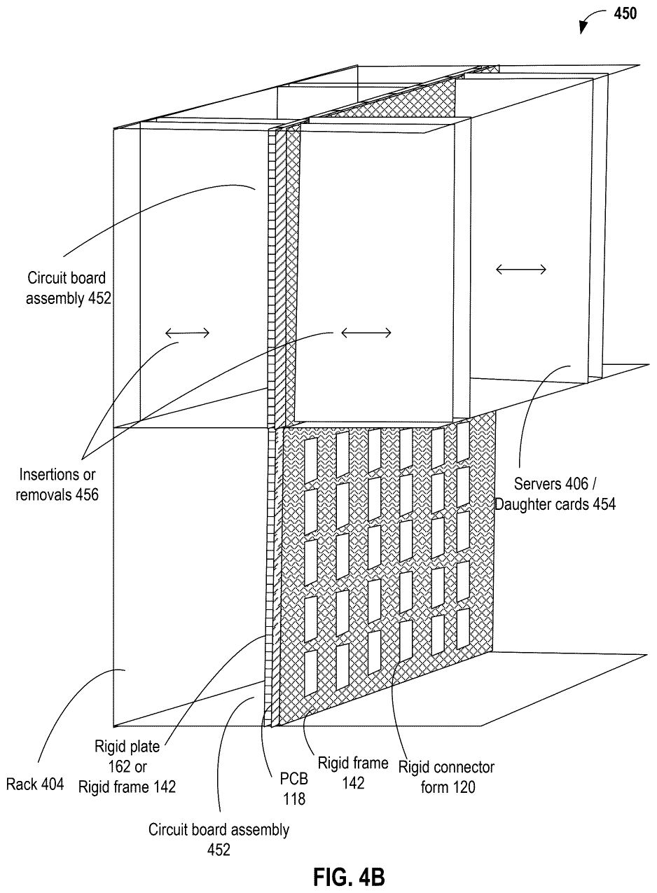

FIG. 1E illustrates aspects 170 of a rigid plate or a rigid frame, according to at least one embodiment. The aspects 170 may be a bottom surface of a rigid frame or of a rigid plate. The bottom surface is generally a reference to the surface subject to interface against the PCB 118. The aspects 170 illustrate that rigid frame pressure interfaces 172 may be provided all throughout the rigid frame 142 or rigid plate 162 to interface with the PCB 118 (as in FIG. 1D). The rigid frame pressure interfaces 172 may be spring-loaded features, such as a ball and spring combination. The rigid frame pressure interfaces 172 may be associated with the flange overlay portions 148 and around the connector form provisions 150. The spring-loaded features may allow equal distribution of pressures or forces associated with insertions or removals of servers or daughter cards with respect to the PCB, which is detailed further in connection with at least FIG. 4B.

The spring-loaded features may allow a tolerance for a pressure applied through the rigid frame to the rigid connector forms. The spring-loaded features may allow a tolerance from a force applied through the rigid frame to the plurality of rigid connector forms. In another example, the spring-loaded features may allow a tolerance from a distance between the rigid frame and the PCB based in part on a warping of the PCB. In yet another example, the spring-loaded features may allow a tolerance from an electrical contact to be made between the surface contact pads and connectors of the rigid connector forms or connectors to be associated with the rigid connector forms.

FIG. 2A illustrates aspects 200 of a dual-sided midplane with rigid connector forms, according to at least one embodiment. The dual-side midplane 202 may be an example of the PCB 118 of FIGS. 1A-1D. In the example, the dual-side midplane 202 may include top-side rigid connector forms 204 and bottom-side rigid connector forms 206. The top-side rigid connector forms 204 and bottom-side rigid connector forms 206 may be examples of the rigid connector forms 120 of FIGS. 1A-1D. As illustrated, in the absence of fastener posts or fasteners through each of the top-side rigid connector forms 204 and bottom-side rigid connector forms 206, each of the top-side rigid connector forms 204 may be closer to the top side of the dual-side midplane 202 and each of the bottom-side rigid connector forms 206 may be closer to each other on the bottom side of the dual-side midplane 202. Moreover, the absence of the fastener posts or fasteners through each of the top-side rigid connector forms 204 and bottom-side rigid connector forms 206 also allows dense layout of interconnects that may be mounted on a same side of a PCB or for connectors located on opposite sides of the PCB, by way of the illustrated dual-side midplane 202. There are no obstructions for screw locations that are in free areas 134 of the dual-side midplane 202.

FIG. 2B illustrates further details 230 of a dual-sided midplane with rigid connector forms, according to at least one embodiment. FIG. 2B illustrates further details 230 of the dual-side midplane 202, as to the top-side rigid connector forms 204 and bottom-side rigid connector forms 206. FIG. 2B specifically illustrates that removed fasteners and unused fastener posts 232, through each of the top-side rigid connector forms 204 and bottom-side rigid connector forms 206, allow each of the top-side rigid connector forms 204 to be closer on the top side of the dual-side midplane 202 and each of the bottom-side rigid connector forms 206 to be closer to each other on the bottom side of the dual-side midplane 202. The removed fasteners and unused fastener posts 232 also allow the dense layout of interconnects, as described in reference to FIG. 2A. In addition, FIG. 2B illustrates that it is possible to retrofit existing midplanes and backplanes using the rigid connector forms 120 and at least the rigid frame 142 over at least the removed fasteners and unused fastener posts 232.

FIG. 2C illustrates further details 250 of a rigid connector form over surface contact pads of a PCB in a transparent section-view, according to at least one embodiment. FIG. 2C illustrates the pins 106 that may extend from the surface contact pads 252. The pins 106 may extend through the rigid connector form 120 to allow connection with an external connector 110 by a plug-in to the rigid connector form 120. The pins 106 may be part of the rigid connector form 120 to extend the surface contact pads 252, in one example. In another example, the external connector 110 may include the pins 106 to reach the surface contact pads 252. The external connector 110 may be supported by a ribbon 114 or other feature to allow communication from the external connector 110 to a circuit of the PCB 118. In this manner, it is possible to couple together 112, by a plug-in for instance, a circuit board rigid connector 102 to the surface contact pads 252 and to external connectors 110.

FIGS. 3A and 3B illustrate details 300, 350 of spring-loaded features of the rigid connector forms, according to at least one embodiment. The spring-loaded features may be embedded in the external flanges, in one example. The spring-loaded features may include at least a pressure interface 302 and a springs 304, which may be constrained within spring apertures 306 of the external flanges 104. The spring-loaded features allow tolerance for one or more of a pressure applied through the rigid frame 142 to the rigid connector forms 120. The spring-loaded features also allow force to be applied through the rigid frame 142 to the rigid connector forms 120. The spring-loaded features also allow a distance between the rigid frame 142 and the PCB 118 based in part on a warping of the PCB 118 that may occur on performance of operations in a signaling circuit. The downward resulting force of the rigid connector form to the PCB ensures that the spring-loaded features also allow an electrical contact to be made between the surface contact pads 252 and connectors (such as the pins 106) of the rigid connector forms 120 or connectors (such as the pins 106) to be associated with the rigid connector forms 120.

The illustrated fasteners 166 may also be in a uniform distribution through the fastener provisions 144, 164, 132 to, along with the spring-loaded features, allow tolerance for one or more of a pressure applied through the rigid frame to the rigid connector forms, a force applied through the rigid frame to the rigid connector forms, a distance between the rigid frame and the PCB based in part on a warping of the PCB, or an electrical contact to be made between the surface contact pads and connectors of the rigid connector forms or connectors to be associated with the rigid connector forms.

FIG. 3C illustrates details 380 in a section view of a rigid frame over an external flange of a rigid connector form, in support of rigid connectors for a PCB, according to at least one embodiment. FIG. 3C illustrates that the rigid connector forms 120, having individual external flanges 104, may be held in position by the rigid frame 142, at flange overlay portions 148. There may be fasteners 166 from above or below the PCB 118, as illustrated. The rigid connector forms 120 can maintain a position for the rigid connector forms 120 with respect to the PCB 118.

FIG. 4A illustrates a datacenter 400 that is subject to embodiments associated with rigid connector forms having individual external flanges in support of rigid connectors for a PCB. The datacenter 400 may include racks 404 that may be associated with servers 406 therein (in a server tray, server box, or server/computer module format), and that may include compute devices therein to perform a workload. Although illustrated as horizontal features, the servers 406 may be vertically provided within a rack 404. Such racks 404 may be tied (such as hardwired or natively within rows of racks) as part of the infrastructure of the datacenter 400. For instance, the racks 404 may be associated with power supply units (PSUs) and may be associated with a busbay 416 to receive and distribute power for the servers 406, these racks 404 may necessarily include power components (such as busbars 418) that are intimately associated with the racks 404. The power components may be part of the infrastructure of the datacenter 400. The racks 404 may include high-speed interconnect, enabling high-speed communication between subsystems, including the servers 406.

The compute devices may be provided on circuit boards and may include processors (such as central processing units (CPUs), quantum processing units (QPUs), graphics processing units (GPUs), data processing units (DPUs), application-specific integrated circuits (ASICs), field-programmable gate arrays (FPGAs), physics processing units (PPUs), or the like), and other components (such as memory, communication modules, input/output modules, and the like).

In at least one embodiment, the datacenter 400 may include one or more rooms 402 of racks 404, where the racks 404 may include server trays or servers 406. The datacenter 400 may be powered from a power distribution 408 system, via one or more transformers 410 (Tr.), so that the power to a switchgear 412 may be suitable for the datacenter. For instance, the power distribution 408 system may be part of a transmission system. The transmission system may provide high-voltage electricity from a utility grid. Each transformer 410 may step down the voltage to a level suitable for the datacenter's equipment and devices, such as the aforementioned processors that may be in the server trays or servers 406 in each rack 404. The switchgear 412 may be able to control, protect, and isolate power in both downstream and upstream directions.

The switchgear 412 may be used to manage flow of electricity in a reliable and efficient manner using switching of electrical circuits for controls and using breakers and fuses to detect and respond to faults or overloads in both downstream and upstream directions. In addition to an external source represented by the transmission systems and to ensure uninterrupted power supply, a backup 414 system, such as a generator or Uninterruptible Power Supply (UPS), may be used with the power distribution 408 system (Power Dist.). In addition, a cooling system 426 may provide at least air cooling for the cold aisle 430 side and passing through the racks 404 to the hot aisle 428 side of the datacenter 400. The movement of the air cooling may be supported by fans, in one example.

The switchgear 412 may be associated with the busbay 416. The busbay 416 may provide power to one or more racks 404. In one example, the busbay 416 may provide power to one or more racks 404 through provided busbars 418. The busbars 418 may be conductive bars that carry electrical current to various loads, including those represented by the aforementioned processors, which may be within the server trays or computer modules (also referenced as servers 406) in each rack 404 of the datacenter 400. The busbars 418 may be provided from copper, aluminum, or a suitable power delivery material. The busbars 418 may be able to work together to handle the high-current demands of the datacenter 400.

The datacenter 400 may include a midplane or a backplane, which may be represented by the PCB 118 and the discussions with respect to FIGS. 2A and 2B. The midplane or the backplane may have the surface contact pads to receive external connectors from components of the datacenter. These components may include the power components, the computing components, and the cooling components described herein. The midplane or the backplane may be associated with rigid connector forms having individual external flanges. The surface contact pads may be individually encompassed by the rigid connector forms. A rigid frame may overlay the external flanges to maintain a position for rigid connector forms to be against the midplane or the backplane.

The datacenter 400 may be such that there are first provisions for first fasteners at a perimeter of the rigid frame. The datacenter 400 may be such that the rigid connector forms are devoid of fasteners to the midplane or the backplane. The datacenter 400 may be such that second provisions are provided for second fasteners at locations that coincide with areas of the midplane or the backplane that are free from circuit or signal components. One or more of the first provisions or the second provisions may be the rigid frame fastener provisions 144 described in at least FIG. 1D. One or more of the first provisions or the second provisions may be subject to the fasteners 166 to maintain a position for rigid connector forms to be against the midplane or the backplane.

The datacenter 400 may be such that the rigid connector forms include an adhesive between an underside of the external flanges and the midplane or the backplane. For example, positions may be determined for the rigid connector forms on the PCB based at least in part on locations of surface contact pads on the PCB. Then, the rigid connector forms may be provided with an adhesive or the PCB may be provided with an adhesive. The adhesive may be provided to be coincidental on the external flange of the rigid connector forms. The adhesive may be between an underside of the individual external flanges and the PCB. Once all the rigid connector forms are adhered to the PCB, the rigid frame may be applied with or without the rigid plate. Fasteners may hold the circuit board assembly of the PCB, the rigid frame, and the rigid plate together at unused areas of the PCB. The datacenter 400 may be such that a rigid plate is associated with the rigid frame from an opposite side of the midplane or the backplane, as described in at least FIG. 1D. The positioning of the rigid plate opposite the midplane or the backplane may be relative to the rigid frame, as also described in connection with FIG. 1D. The datacenter 400 may be such that the rigid plate includes second provisions, such as the rigid plate fastener provisions 164, to receive fasteners through first provisions, such as the rigid frame fastener provisions 144, of the rigid frame.

The datacenter 400 may be such that there are spring-loaded features associated with the external flanges of individual ones of the rigid connector forms, as described in connection with FIGS. 3A and 3B. The spring-loaded features allow tolerance for one or more of a pressure applied through the rigid frame to the rigid connector forms, a force applied through the rigid frame to the rigid connector forms, a distance between the rigid frame and the midplane or the backplane, based in part on a warping of the midplane or the backplane, or an electrical contact to be made between the surface contact pads and connectors of the rigid connector forms or connectors to be associated with the rigid connector forms. The datacenter 400 may be such that connectors of the rigid connector forms may couple to the surface contact pads. External connectors in the datacenter 400 are to plug to the connectors to allow communication from the external connectors to a circuit of the midplane or the backplane. The datacenter 400 may be such that there are pins extending from the surface contact pads in the datacenter. The pins may extend through the rigid connector forms to allow connection with external connectors by a plug-in to the rigid connector forms.

FIG. 4B illustrates aspects 400 of an example rack to apply at least one embodiment in FIGS. 1-3C and 5-7. The aspects 400 illustrate that a rack 404 may have at least one circuit board assembly 452. Although illustrated as open, the rack 404 may be fully enclosed with front, back, side, and top covers or access panels. Also, although illustrated at a high-level flat structure, the circuit board assembly 452 may include at least one PCB 118 and one or more rigid frames 142 (also, as illustrated and described in at least FIG. 1D). When used as a backplane, a circuit board assembly may include a single rigid frame 142 and may include a rigid plate 162 opposite the rigid frame 162 (also, as illustrated and described in at least FIG. 1D). The rigid plate 162 may not include connector form provisions 150 for rigid connector forms 120. The circuit board assembly 452 may include surface contact pads (as in FIG. 2C). The surface contact pads may be individually encompassed by rigid connector forms 120 (also in FIG. 2C). The rigid frame may overlay the individual external flanges of the rigid connector form to maintain a position for the rigid connector forms 120 with respect to the PCB 118 (as illustrated in and discussed with respect to at least FIG. 3C).

The circuit board assembly 452 may be a backplane or a midplane. In the aspects 400 in FIG. 4B, the circuit board assembly 452 is a midplane which is located at a middle of a rack 404. The midplane may receive servers 406 in a vertical board format or daughter cards 454, which may be pushed for insertion 456 against the pins 106 (in FIG. 2C, for instance) of the midplane forming one or many connectors between the midplane and the servers 406 or the daughter cards 454. The use of the rigid frame within he circuit board assembly 452 may allow tolerance from a pressure applied through the rigid frame during insertions 456 or removals associated with the servers 406 or daughter cards 454. The pressure may be on the rigid connector forms from the insertions 456 representing, at least in part, a force applied through the rigid frame to the rigid connector forms. One or more of the rigid connector forms, the rigid frame, or the rigid plate may help maintain integrity of the circuit board assembly 452 through multiple insertions and removals 456 performed for the servers 406 or daughter cards 454.

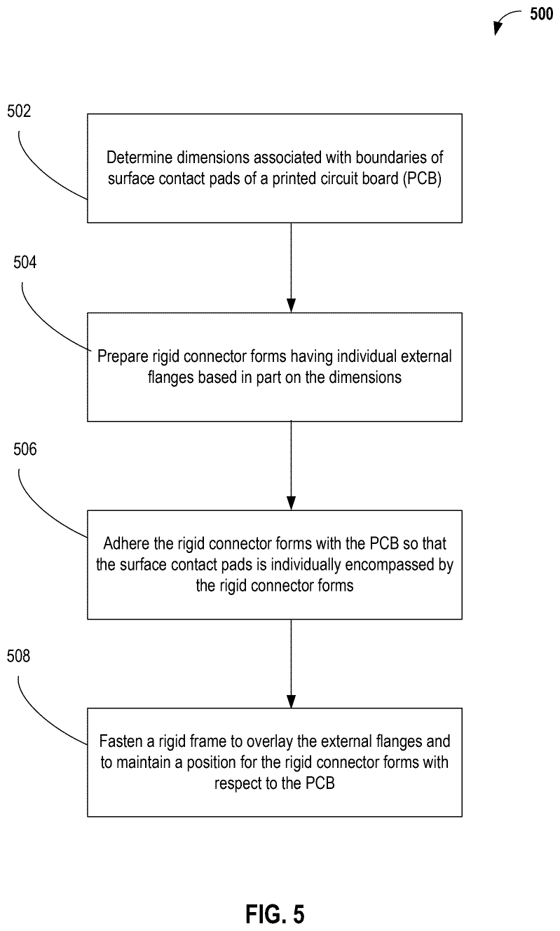

FIG. 5 illustrates a process flow or method 500 associated with rigid connectors for a PCB, according to at least one embodiment. The method 500 may include a step to determine 502 dimensions associated with boundaries of surface contact pads of a PCB. The method 500 may include a step to prepare 504 rigid connector forms having individual external flanges based in part on the dimensions. The method 500 may include a step to adhere 506 the rigid connector forms with the PCB so that the surface contact pads are individually encompassed by the plurality of rigid connector forms. The method 500 may include a step to fasten 508 a rigid frame to overlay the external flanges and to maintain a position for the rigid connector forms with respect to the PCB.

The method 500 may include a step or sub-step where the rigid frame includes one or more of provisions for fasteners at a perimeter of the rigid frame and wherein the plurality of rigid connector forms is devoid of fasteners to the PCB, or provisions for fasteners at locations that coincide with areas of the PCB that are free from circuit or signal components. The method 500 may include a step or sub-step where the rigid frame is associated with rigid frame pressure interfaces, provided all throughout the rigid frame and/or the rigid plate, as detailed in connection with at least FIG. 1E. The rigid frame pressure interfaces are provided in locations to allow an interface with the PCB. The rigid frame pressure interfaces may be spring-loaded features, such as a ball and spring combination. The rigid frame pressure interfaces may be associated with the flange overlay portions and around the connector form provisions.

The method 500 may include a step or sub-step to associate a rigid plate with the rigid frame from an opposite side of the PCB relative to the rigid frame. The rigid plate may include second provisions to receive fasteners through first provisions of the rigid frame. The method 500 may include a step or sub-step to associate spring-loaded features with the external flanges of individual ones of the rigid connector forms. The spring-loaded features may allow tolerance for one or more of a pressure applied through the rigid frame to the rigid connector forms, a force applied through the rigid frame to the rigid connector forms, a distance between the rigid frame and the PCB based in part on a warping of the PCB, or an electrical contact to be made between the surface contact pads and connectors of the rigid connector forms or connectors to be associated with the rigid connector forms.

The method 500 may include a step or sub-step to couple connectors of the rigid connector forms to the surface contact pads. External connectors may plug into the connectors to allow communication from the external connectors to a circuit of the PCB. The method 500 may include a step or sub-step to allow pins to extend from the surface contact pads and through the rigid connector forms. This may allow a connection with external connectors by a plug-in to the rigid connector forms.

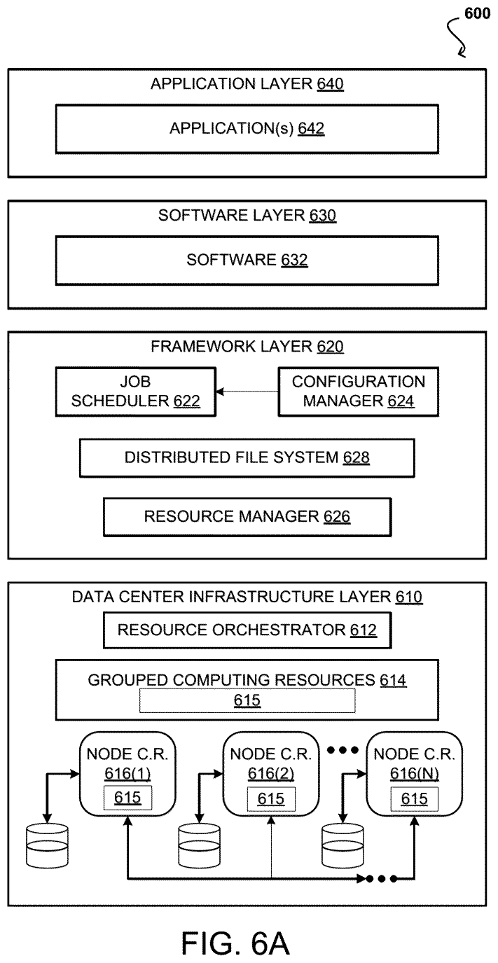

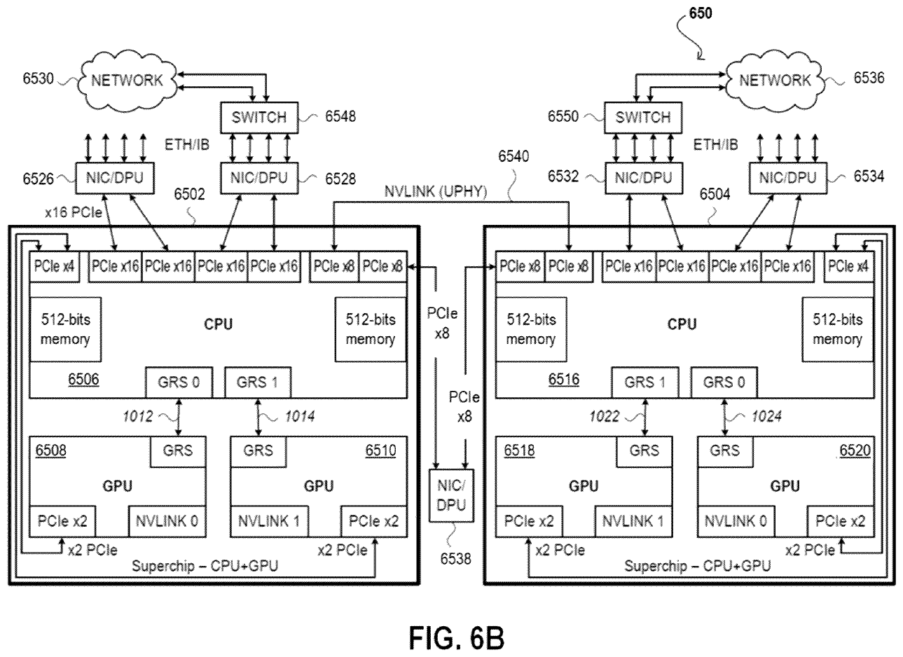

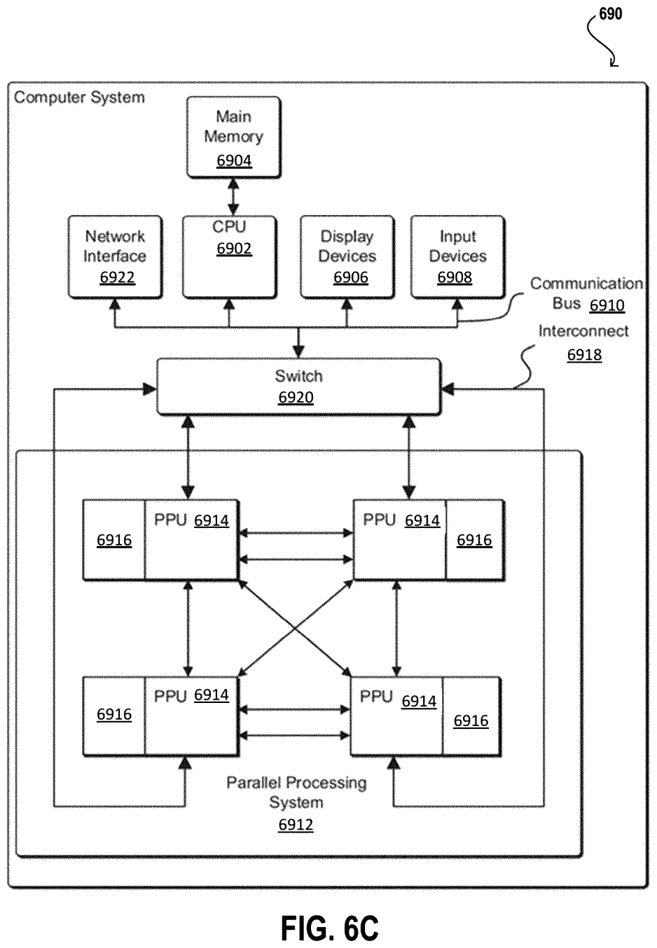

FIG. 6A illustrates an example datacenter 600, in which at least one embodiment may be used. In at least one embodiment, datacenter 600 includes a datacenter infrastructure layer 610, a framework layer 620, a software layer 630, and an application layer 640. FIG. 6A illustrates an example datacenter 600, in which at least one embodiment may be used. In at least one embodiment, datacenter 600 includes a datacenter infrastructure layer 610, a framework layer 620, a software layer 630, and an application layer 640. A datacenter 600 may include one or more racks, such as described in connection with at least FIGS. 1A and 1B. The racks may include one or more server trays. There may be one or more electronic components in the one or more server trays to perform at least part of a workload in the datacenter. The racks and server trays may be represented by at least the datacenter infrastructure layer 610. The electronic components may be presented by the node computing resources 616(1)-616(N) that may be subject to cooling using cold plates.

In another example, the datacenter 600 may include a circuit board assembly having a PCB with surface contact pads. The surface contact pads may be individually encompassed by rigid connector forms having individual external flanges. A rigid frame overlies the external flanges to maintain a position for the plurality of rigid connector forms with respect to the PCB.

In at least one embodiment, as shown in FIG. 6A, datacenter infrastructure layer 610 may include a resource orchestrator 612, grouped computing resources 614, and node computing resources (“node C.R.s”) 616(1)-616(N), where “N” represents any whole, positive integer. In at least one embodiment, node C.R.s 616(1)-616(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 616(1)-616(N) may be a server having one or more of above-mentioned computing resources.

In at least one embodiment, grouped computing resources 614 may include separate groupings of node C.R.s housed within one or more racks (not shown), or many racks housed in datacenters at various geographical locations (also not shown). Separate groupings of node C.R.s within grouped computing resources 614 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 612 may configure or otherwise control one or more node C.R.s 616(1)-616(N) and/or grouped computing resources 614. In at least one embodiment, resource orchestrator 612 may include a software design infrastructure (“SDI”) management entity for datacenter 600. In at least one embodiment, resource orchestrator may include hardware, software or some combination thereof.

In at least one embodiment, as shown in FIG. 6A, framework layer 620 includes a job scheduler 622, a configuration manager 624, a resource manager 626 and a distributed file system 628. In at least one embodiment, framework layer 620 may include a framework to support software 632 of software layer 630 and/or one or more application(s) 642 of application layer 640. In at least one embodiment, software 632 or application(s) 642 may respectively include web-based service software or applications, such as those provided by Amazon Web Services, Google Cloud and Microsoft Azure. In at least one embodiment, framework layer 620 may be, but is not limited to, a type of free and open-source software web application framework such as Apache Spark™ (hereinafter “Spark”) that may use distributed file system 628 for large-scale data processing (e.g., “big data”). In at least one embodiment, job scheduler 622 may include a Spark driver to facilitate scheduling of workloads supported by various layers of datacenter 600. In at least one embodiment, configuration manager 624 may be capable of configuring different layers such as software layer 630 and framework layer 620, including Spark and distributed file system 628 for supporting large-scale data processing. In at least one embodiment, resource manager 626 may be capable of managing clustered or grouped computing resources mapped to or allocated for support of distributed file system 628 and job scheduler 622. In at least one embodiment, clustered or grouped computing resources may include grouped computing resource 614 at datacenter infrastructure layer 610. In at least one embodiment, resource manager 626 may coordinate with resource orchestrator 612 to manage these mapped or allocated computing resources.

In at least one embodiment, software 632 included in software layer 630 may include software used by at least portions of node C.R.s 616(1)-616(N), grouped computing resources 614, and/or distributed file system 628 of framework layer 620. The one or more types of software may include, but are not limited to, Internet web page search software, e-mail virus scan software, database software, and streaming video content software.

In at least one embodiment, application(s) 642 included in application layer 640 may include one or more types of applications used by at least portions of node C.R.s 616(1)-616(N), grouped computing resources 614, and/or distributed file system 628 of framework layer 620. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any configuration manager 624, resource manager 626, and resource orchestrator 612 may implement any number and type of self-modifying actions based on any amount and type of data acquired in any technically feasible fashion. In at least one embodiment, self-modifying actions may relieve a datacenter operator of datacenter 600 from making possibly bad configuration decisions and possibly avoiding underused and/or poor performing portions of a datacenter.

In at least one embodiment, datacenter 600 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 600. In at least one embodiment, trained machine learning models corresponding to one or more neural networks may be used to infer or predict information using resources described above with respect to datacenter 600 by using weight parameters calculated through one or more training techniques described herein.

In at least one embodiment, the datacenter may use CPUs, application-specific integrated circuits (ASICs), GPUs, FPGAs, DPUs, QPUs or PPUs, or other hardware to perform training and/or inferencing using above-described resources. Moreover, one or more software and/or hardware resources described above may be configured as a service to allow users to train or perform inferencing of information, such as image recognition, speech recognition, or other artificial intelligence services.

Inference and/or training logic 615 are used to perform inferencing and/or training operations associated with one or more embodiments. In at least one embodiment, inference and/or training logic 615 may be used in system FIG. 6A for inferencing or predicting operations based, at least in part, on weight parameters calculated using neural network training operations, neural network functions and/or architectures, or neural network use cases described herein.

FIG. 6B is a block diagram that schematically illustrates a computing system that may be a datacenter or a High-Performance Computing (HPC) cluster, in which at least one embodiment from FIGS. 1A-5 may be used. The computing system 650 may include a plurality of subsystems, e.g. multiple processing devices coupled to each other, multiple network devices, and multiple networks, according to at least one embodiment. The computing system 650 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 650 and to one or more external networks 6530, 6536. In the present example, system 650 comprises a packet switch 6548 that connects NIC/DPU 6528 to network 6530, and a packet switch 6550 that connects NIC/DPU 6532 to network 6536.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 650 can include one or more CPUs and one or more GPUs.

FIG. 6B also demonstrates an example architecture of a multi-GPU architecture. As illustrated in the figure, computing system 650 includes a processing device 6502 with a multi-GPU architecture. In particular, processing device 6502 may be a system-on-chip and includes multiple subsystems such as a CPU 6506, a GPU 6508, and a GPU 6510. CPU 6506 can be coupled to GPU 6508 via a die-to-die (D2D) or chip-to-chip (C2C) interconnect 6512, such as a Ground-Referenced Signaling interconnect (GRS interconnect). CPU 6506 can be coupled to GPU 6510 via a D2D or C2C interconnect 6514. CPU 6506 can also couple to GPU 6508 and GPU 6510 via PCIe interconnects.

CPU 6506 can be coupled to one or more NICs or DPUs, which are coupled to one or more networks. For example, as illustrated in FIG. 6B, CPU 6506 is coupled to a first NIC/DPU 6526, which is coupled to a network 6530. CPU 6506 is also coupled to a second NIC/DPU 6528, which is coupled to network 6530 via switch 6548. NIC/DPU 6526 and NIC/DPU 6528 can be coupled to network 6530 over Ethernet (ETH), NVLINK or InfiniBand (IB) connections, for example.

Computing system 650 also includes a processing device 6504 with a multi-GPU architecture. In particular, the processing device 6504 includes multiple subsystems including a CPU 6516, a GPU 6518, and a GPU 6520. CPU 6516 can be coupled to GPU 6518 via an D2D or C2C interconnect 6522. CPU 6516 can be coupled to GPU 6520 via a D2D or C2C interconnect 6524. CPU 6516 can also couple to GPU 6518 and GPU 6520 via PCIe interconnects. CPU 6516 can be coupled to one or more NICs or DPUs, which are coupled to one or more networks. For example, as illustrated in FIG. 6B CPU 6516 is coupled to a first NIC/DPU 6532, which is coupled to a network 6536. CPU 6516 is also coupled to a second NIC/DPU 6534, which is coupled to network 6536 via switch 6550. NIC/DPU 6532 and NIC/DPU 6534 can be coupled to network 6536 over Ethernet (ETH), NVLINK or InfiniBand (IB) connections.

In at least one embodiment, processing device 6502 and processing device 6504 can communicate with each other via a NIC/DPU 6538, such as over PCIe interconnects. Processing device 6502 and processing device 6504 can also communicate with each other over a high-bandwidth communication interconnects 6540, such as an NVLink interconnect or other high-speed interconnects. The packet switches in FIG. 6B may comprise, for example, Nvidia Quantum-2 switches. The NICs/DPUs in the figure may comprise, for example, Nvidia Bluefield DPUs.

In various embodiments, any of the network devices of the computing system 650, e.g., any of NICs/DPUs 6526, 6528, 6532, 6534 and 6538, and/or any of switches 6548 and 6550, may include a shaped leak sensor that can match a geometry around components and features in the computing system 650 and that can be communicatively coupled together to extend leak detection capabilities.

FIG. 6C illustrates a computer system 690, according to at least one example, in which at least one embodiment from FIGS. 1A-5 may be used. In at least one embodiment, computer system 690 is configured to implement various processes and methods described throughout this disclosure.

In at least one embodiment, computer system 690 comprises, without limitation, at least one central processing unit (“CPU”) 6902 that is connected to a communication bus 6910 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 690 includes, without limitation, a main memory 6904 and control logic (e.g., implemented as hardware, software, or a combination thereof) and data are stored in main memory 6904 which may take the form of random access memory (“RAM”). In at least one embodiment, a network interface subsystem (“network interface”) 6922 provides an interface to other computing devices and networks for receiving data from and transmitting data to other systems from computer system 690.

In at least one embodiment, computer system 690, in at least one embodiment, includes, without limitation, input devices 6908, parallel processing system 6912, and display devices 6906 which can be implemented using a conventional cathode ray tube (“CRT”), liquid crystal display (“LCD”), light emitting diode (“LED”), plasma display, or other suitable display technologies. In at least one embodiment, user input is received from input devices 6908 such as keyboard, mouse, touchpad, microphone, and more. In at least one embodiment, each of the foregoing modules can be situated on a single semiconductor platform to form a processing system.

In at least one embodiment, computer programs in the form of machine-readable executable code or computer control logic algorithms are stored in main memory 6904 and/or secondary storage. Computer programs, if executed by one or more processors, enable system 690 to perform various functions in accordance with at least one embodiment. Memory 6904, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in the context of CPU 6902; parallel processing system 6912; an integrated circuit capable of at least a portion of capabilities of both CPU 6902; parallel processing system 6912; a chipset (e.g., a group of integrated circuits designed to work and sold as a unit for performing related functions, etc.); and any suitable combination of integrated circuit(s).

In at least one embodiment, architecture and/or functionality of various previous figures are implemented in the context of a general computer system, a circuit board system, a game console system dedicated for entertainment purposes, an application-specific system, and more. In at least one embodiment, computer system 690 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 6912 includes, without limitation, a plurality of parallel processing units (“PPUs”) 6914 and associated memories 6916. In at least one embodiment, PPUs 6914 are connected to a host processor or other peripheral devices via an interconnect 6918 and a switch 6920 or multiplexer. In at least one embodiment, parallel processing system 6912 distributes computational tasks across PPUs 6914 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 6914, although such shared memory may incur performance penalties relative to use of local memory and registers resident to a PPU 6914. In at least one embodiment, operation of PPUs 6914 is synchronized through use of a command such as_syncthreads( ), wherein all threads in a block (e.g., executed across multiple PPUs 6914) reach a certain point of execution of code before proceeding.

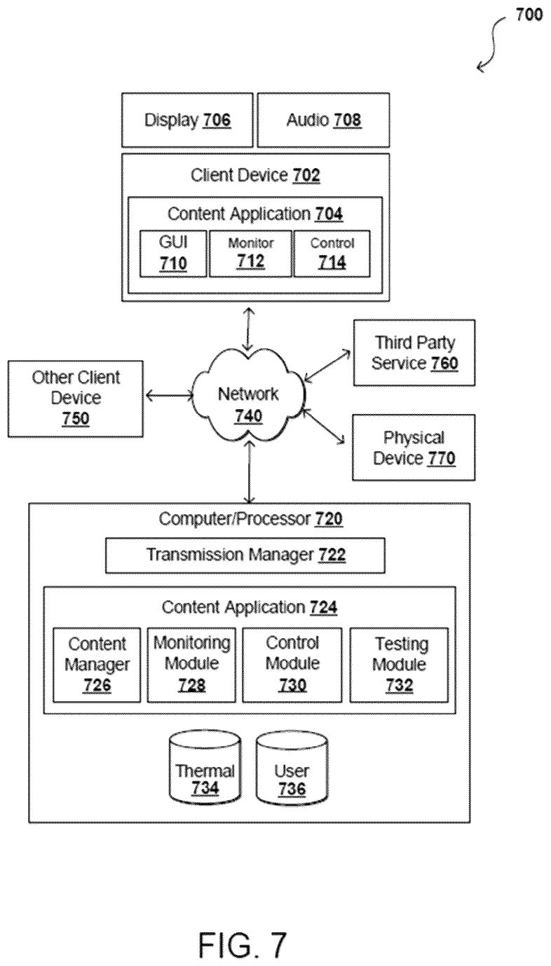

FIG. 7 illustrates an example network configuration 700 of components that can be used to implement aspects of various embodiments, such as to provide, generate, modify, encode, process, fuse, and/or transmit generated image data, calculated measurements, or other such content. In at least one embodiment, a client device 702 can generate or receive data for a session using components of a content application 704 on the client device 702 and data stored locally on that client device. In at least one embodiment, a content application 724 executing on a computer or processor 720 (e.g., a cloud server or control system) may initiate a session associated with at least one client device 702 (e.g., a vehicle or robot), as may use a session manager and user data stored in a user database 736, and can cause content such as liquid coolant or server thermal data to be selected and/or retrieved from a repository 734 to be used by a testing module 732 to calculate one or more performance metrics for a monitoring module 728, which can provide flow data or thermal data to a control module 730 to control a flow or temperature, in an environment where the data is to be used to determine appropriate operation. A content manager 726 may work with these various modules to perform testing and analysis, and potentially instruct any actions to be taken in response to a performance metric failing to satisfy an operational requirements. At least a portion of this data or instructional content can be transmitted to the client device 702 and/or a physical device 770 using an appropriate transmission manager 722 to send by download, streaming, or another such transmission channel. An encoder may be used to encode and/or compress at least some of this data before transmitting to the client device 702. In at least one embodiment, the client device 702 receiving such content can provide this content to a corresponding content application 704, which may also or alternatively include a graphical user interface 710, a flow monitor module 712, and a control module 714 for use in providing, synthesizing, rendering, compositing, modifying, or using content for presentation, navigation, control, (or other purposes) on or by the client device 702, such as may be transmitted to the physical device 770. In some embodiments, the computer/processor 720 and client device 702 may be able to communicate directly without needing to transmit data over a network 740, in order to avoid issues with latency and availability, etc. A decoder may also be used to decode data received over the network 740 for presentation via client device 702, such as imaging content or performance metrics through a display device 706 and audio, such as corresponding sounds or synthesized speech, through at least one audio playback device 708, such as speakers or headphones. In at least one embodiment, at least some of this content may already be stored on, rendered on, or accessible to client device 702 such that transmission over a network 740 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 720, or user database 736, to the client device 702. In at least one embodiment, at least a portion of this content can be obtained, enhanced, and/or streamed from another source, such as a third party service 760 or other client device 750, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit).

In at least one embodiment, a cold plate herein may include adjustable fins forming microchannels for fluid to flow through. In at least one embodiment, fins in a cold plate allow transfer of heat from at least one associated computing device to a fluid flowing through microchannels formed between multiple fins. In at least one embodiment, fins of a cold plate are dynamically and adjustable in real time to allow transfer of more heat from at least one computing device to a fluid that flows through a cold plate having fins. In at least one embodiment, such fins may be adjusted by a processor or processorless system based in part on a temperature determined, such as sensed, for a cold plate. In at least one embodiment, a temperature may be associated with at least one computing device, a workload of at least one computing device, or a fluid at different time periods and at an entry, and at an egress of a cold plate. In at least one embodiment, a processorless system may rely on a thermal property of at least two materials used to form fins for a cold plate so that such fins may react without a processor to cause exposure of more surface area to a fluid. In at least one embodiment, such fins may include an overlapping portion that may be caused to be exposed by action of a control mechanism or by properties of at least two materials associated together to form a fin.

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a datacenter or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

Other variations are within the spirit of present disclosure. Thus, while disclosed techniques are susceptible to various modifications and alternative constructions, certain illustrated embodiments thereof are shown in drawings and have been described in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of the term ‘set’ (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, the term “plurality” indicates a state of being plural (e.g., “a plurality of items” indicates multiple items). In at least one embodiment, the number of items in a plurality is at least two, but can be more when so indicated either explicitly or by context. Further, unless stated otherwise or otherwise clear from context, the phrase “based on” means “based at least in part on” and not “based solely on.”

Operations of processes described herein can be performed in any suitable order and may be automated unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in the form of a computer program comprising a plurality of instructions executable by one or more processors.

In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause the computer system to perform operations described herein. In at least one embodiment, a set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of the instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operations such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment, combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to the practice of the disclosure.

In description and claims, terms “coupled” and “connected,” along with their derivatives, may be used. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, a “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as the system may embody one or more methods and methods may be considered a system.

In present document, references may be made to obtaining, acquiring, receiving, or inputting analog or digital data into a subsystem, computer system, or computer-implemented machine. In at least one embodiment, the process of obtaining, acquiring, receiving, or inputting analog and digital data can be accomplished in a variety of ways, such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing an entity to acquiring entity. References may also be made to providing, outputting, transmitting, sending, or presenting analog or digital data. In at least one embodiment, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A circuit board assembly comprising a printed circuit board (PCB) with a plurality of surface contact pads, wherein the plurality of surface contact pads is individually encompassed by a plurality of rigid connector forms having individual external flanges, and wherein a rigid frame overlies the individual external flanges to maintain a position for the plurality of rigid connector forms with respect to the PCB.

2. The circuit board assembly of claim 1, wherein the rigid frame comprises provisions for fasteners at a perimeter of the rigid frame and wherein the plurality of rigid connector forms is devoid of fasteners to the PCB.

3. The circuit board assembly of claim 1, wherein the rigid frame comprises provisions for fasteners at locations that coincide with areas of the PCB that are free from circuit or signal components.

4. The circuit board assembly of claim 1, wherein the plurality of rigid connector forms comprises an adhesive between an underside of the individual external flanges and the PCB.

5. The circuit board assembly of claim 1, further comprising:
a rigid plate associated with the rigid frame from an opposite side of the PCB relative to the rigid frame, wherein the rigid plate comprises second provisions to receive fasteners through first provisions of the rigid frame.

6. The circuit board assembly of claim 1, further comprising:
spring-loaded features associated with the individual external flanges of individual ones of the plurality of rigid connector forms, wherein the spring-loaded features allow tolerance for one or more of a pressure applied through the rigid frame to the plurality of rigid connector forms, a force applied through the rigid frame to the plurality of rigid connector forms, a distance between the rigid frame and the PCB based in part on a warping of the PCB, or an electrical contact to be made between the plurality of surface contact pads and connectors of the plurality of rigid connector forms or connectors to be associated with the plurality of rigid connector forms.

7. The circuit board assembly of claim 1, further comprising:
connectors of the plurality of rigid connector forms to couple to the plurality of surface contact pads, wherein external connectors are to plug to the connectors to allow communication from the external connectors to a circuit of the PCB.

8. The circuit board assembly of claim 1, further comprising:
pins extending from the plurality of surface contact pads, the pins to extend through the plurality of rigid connector forms to allow connection with external connector by a plug-in to the plurality of rigid connector forms.

9. A system comprising:
a midplane or a backplane with a plurality of surface contact pads to receive a plurality of external connectors from components of a signaling circuit;
a plurality of rigid connector forms having individual external flanges, wherein the plurality of surface contact pads is individually encompassed by the plurality of rigid connector forms; and
a rigid frame overlaying the individual external flanges to maintain a position for the plurality of rigid connector forms to be against the midplane or the backplane.

10. The system of claim 9, wherein the rigid frame comprises one or more of:
first provisions for first fasteners at a perimeter of the rigid frame and wherein the plurality of rigid connector forms is devoid of fasteners to the midplane or the backplane; or
second provisions for second fasteners at locations that coincide with areas of the midplane or the backplane that are free from circuit or signal components.

11. The system of claim 9, wherein the plurality of rigid connector forms comprises an adhesive between an underside of the individual external flanges and the midplane or the backplane.

12. The system of claim 9, further comprising:
a rigid plate associated with the rigid frame from an opposite side of the midplane or the backplane, relative to the rigid frame, wherein the rigid plate comprises second provisions to receive fasteners through first provisions of the rigid frame.

13. The system of claim 9, further comprising:
spring-loaded features associated with the individual external flanges of individual ones of the plurality of rigid connector forms, wherein the spring-loaded features allow tolerance for one or more of a pressure applied through the rigid frame to the plurality of rigid connector forms, a force applied through the rigid frame to the plurality of rigid connector forms, a distance between the rigid frame and the midplane or the backplane, based in part on a warping of the midplane or the backplane, or an electrical contact to be made between the plurality of surface contact pads and connectors of the plurality of rigid connector forms or connectors to be associated with the plurality of rigid connector forms.

14. The system of claim 9, further comprising:
connectors of the plurality of rigid connector forms to couple to the plurality of surface contact pads, wherein external connectors are to plug to the connectors to allow communication from the external connectors to a circuit of the midplane or the backplane.

15. The system of claim 9, further comprising:
pins extending from the plurality of surface contact pads, the pins to extend through the plurality of rigid connector forms to allow connection with external connectors by a plug-in to the plurality of rigid connector forms.

16. A method for connections on a circuit board assembly, the method comprising:
determining dimensions associated with boundaries of a plurality of surface contact pads of a printed circuit board (PCB);
preparing a plurality of rigid connector forms having individual external flanges based in part on the dimensions;
adhering the plurality of rigid connector forms with the PCB so that the plurality of surface contact pads is individually encompassed by the plurality of rigid connector forms; and
fastening a rigid frame to overlay the individual external flanges and to maintain a position for the plurality of rigid connector forms with respect to the PCB.

17. The method of claim 16, wherein the rigid frame comprises one or more of:
provisions for fasteners at a perimeter of the rigid frame and wherein the plurality of rigid connector forms is devoid of fasteners to the PCB; or
provisions for fasteners at locations that coincide with areas of the PCB that are free from circuit or signal components.

18. The method of claim 16, further comprising:
associating a rigid plate with the rigid frame from an opposite side of the PCB relative to the rigid frame, wherein the rigid plate comprises second provisions to receive fasteners through first provisions of the rigid frame.

19. The method of claim 16, further comprising:
associating spring-loaded features with the individual external flanges of individual ones of the plurality of rigid connector forms, wherein the spring-loaded features allow tolerance for one or more of a pressure applied through the rigid frame to the plurality of rigid connector forms, a force applied through the rigid frame to the plurality of rigid connector forms, a distance between the rigid frame and the PCB based in part on a warping of the PCB, or an electrical contact to be made between the plurality of surface contact pads and connectors of the plurality of rigid connector forms or connectors to be associated with the plurality of rigid connector forms.

20. The method of claim 16, further comprising one or more of:
coupling connectors of the plurality of rigid connector forms to the plurality of surface contact pads, wherein external connectors are to plug to the connectors to allow communication from the external connectors to a circuit of the PCB; or
allowing pins to extend from the plurality of surface contact pads and through the plurality of rigid connector forms to allow connection with external connectors by a plug-in to the plurality of rigid connector forms.

21. A datacenter comprising:
a midplane or a backplane with a plurality of surface contact pads to receive a plurality of external connectors from components of the datacenter;
a plurality of rigid connector forms having individual external flanges, wherein the plurality of surface contact pads is individually encompassed by the plurality of rigid connector forms; and
a rigid frame overlaying the individual external flanges to maintain a position for the plurality of rigid connector forms to be against the midplane or the backplane.

22. The datacenter of claim 21, wherein the rigid frame comprises rigid frame pressure interfaces to allow equal distribution of forces or pressures from removal or insertions associated with the external connectors and with respect to the midplane or the backplane.

23. The datacenter of claim 21, wherein the midplane or the backplane is to receive daughter cards or servers comprising the external connectors.

24. The datacenter of claim 21, wherein the plurality of surface contact pads include power or high-speed communication contact pads.
